(19) United States
(12) Patent Application Publication
(10) Pub. No.: US 2002/0043709 A1
(43) Pub. Date: Apr. 18, 2002

(54) Stackable integrated circuit

(76) Inventors: Nai Hua Yeh, Hsinchu Hsien (TW); Mon Nan Ho, Hsinchu Hsien (TW); Hsiu Wen Tu, Hsinchu Hsien (TW); Yung Sheng Chiu, Hsinchu Hsien (TW); Kuo Feng Peng, Hsinchu Hsien (TW); Jichen Wu, Hsinchu Hsien (TW); Kuang Yu Fan, Hsinchu Hsien (TW); Wen Chuan Chen, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/768,982

(22) Filed: Jan. 23, 2001

Related U.S. Application Data
(63) Continuation-in-part of application No. 09/687,953, filed on Oct. 13, 2000.

(51) Int. Cl. H01L 23/02

(52) U.S. Cl. 257/686

(57) ABSTRACT

A stackable integrated circuit for electrically connecting to a circuit board and for a second integrated circuit body to be stacked on. The stackable integrated circuit includes an integrated circuit body, a plurality of first contacts, a projecting layer, and a plurality of second contacts. The integrated circuit body has a first surface and a second surface opposite to the first surface. The first contacts are formed on the first surface of the integrated circuit body for electrically connecting the integrated circuit body to the circuit board. The projecting layer is arranged on the second surface of the integrated circuit body. The second contacts are formed on the projecting layer for electrically connecting the integrated circuit body to a second integrated circuit body.

### CROSS REFERENCE TO RELATED APPLICATION

This application is a Continuation-In-Part of U.S. patent application Ser. No. 09/687,953, filed Oct. 13, 2000, titled “Stackable Integrated Circuit” which is hereby incorporated by reference to the same extent as is fully set forth herein.

### BACKGROUND OF THE INVENTION

1. Field of the Invention

The invention relates to a stackable integrated circuit, in particular, to an integrated circuit capable of being effectively stacked by another integrated circuit so as to facilitate the manufacturing processes.

2. Description of the Related Art

In the current technological field, every product needs to be light, thin, and small. Therefore, it is preferable that the integrated circuit has a small volume in order to meet the demands of the products. In the prior art, even if the volumes of integrated circuits are small, they only can be electrically connected to the circuit board in parallel. Because the area of the circuit board is limited, it is not possible to increase the number of the integrated circuits mounted on the circuit board. Therefore, it is difficult to make the products small, thin, and light.

The U.S. patent application Ser. No. 09/687,953, filed Oct. 13, 2000 discloses a stackable integrated circuit. The stackable integrated circuits can be stacked to each other so as to increase the number of integrated circuits arranged on a circuit board. Thus, the functions of the products can be increased. Furthermore, the products can also be made small, thin, and light.

Referring to FIG. 1, an upper integrated circuit 10 is stacked on a lower integrated circuit 12 via a plurality of large metallic balls 14. It is difficult to manufacture the large metallic balls 14. Furthermore, the yield of the large metallic balls 14 is low and the amount of the material of the metallic balls 14 is large. Thus, the manufacturing costs of the large metallic balls are high.

In view of the above-mentioned disadvantages, it is important to provide another stackable integrated circuit in order to facilitate the stacking processes, increase the yield and the manufacturing speed, and lower down the manufacturing costs effectively.

### SUMMARY OF THE INVENTION

It is therefore an object of the invention to provide a stackable integrated circuit having the functions of facilitating the stacking processes so that the manufacturing speed of the circuit can be increased.

It is therefore another object of the invention to provide a stackable integrated circuit having the functions of increasing the yield of the products so that the manufacturing costs of the products can be increased.

According to one aspect of the invention, there is provided a stackable integrated circuit for electrically connecting to a circuit board and for a second integrated circuit body to be stacked on. The stackable integrated circuit includes an integrated circuit body, a plurality of first contacts, a projecting layer, and a plurality of second contacts. The integrated circuit body has a first surface and a second surface opposite to the first surface. The first contacts are formed on the first surface of the integrated circuit body for electrically connecting the integrated circuit body to the circuit board. The projecting layer is arranged on the second surface of the integrated circuit body. The second contacts are formed on the projecting layer for electrically connecting the integrated circuit body to a second integrated circuit body.

By using the above-mentioned structure, it is more convenient for stacking a plurality of integrated circuits. Furthermore, the electrical connection processes between adjacent integrated circuits can be facilitated. Moreover, the electrical connection effect can be improved so as to improve the yield and increase the manufacturing speed.

### BRIEF DESCRIPTION OF THE DRAWINGS

FIG. 1 is a schematic illustration showing the implementation of the stackable integrated circuits in accordance with the U.S. patent application Ser. No. 09/687,953.

FIG. 2 a schematic illustration showing the implementation of the invention.

FIG. 3 is an exploded view showing the stackable integrated circuit of the invention.

FIG. 4 is a cross-sectional view showing the combined integrated circuit of FIG. 3.

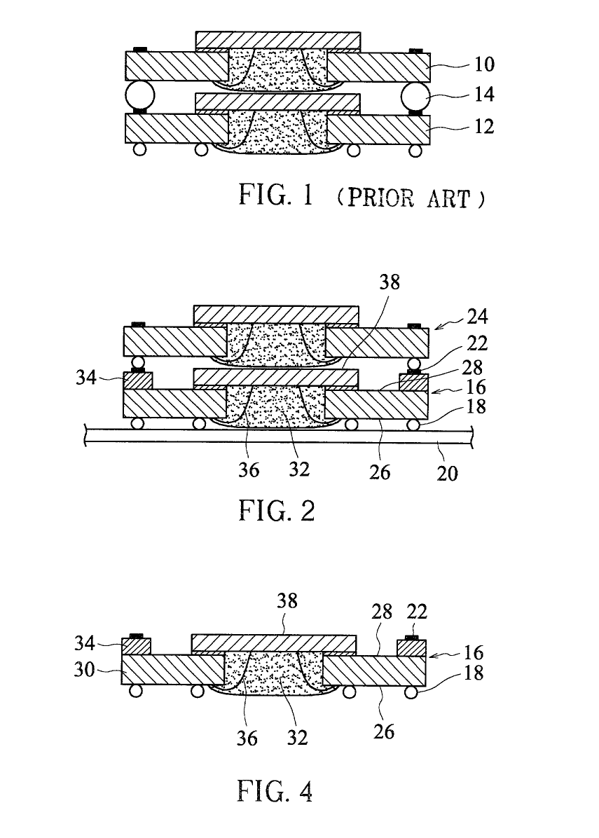

### DETAIL DESCRIPTION OF THE INVENTION

The stackable integrated circuit of the invention will be described in detail with reference to the following drawings.

Referring to FIG. 2, an integrated circuit body 16 is electrically connected to a circuit board 20 via a plurality of first contacts 18. The integrated circuit body 16 is also electrically connected to a second integrated circuit body 24 via a plurality of second contacts 22. By using such a structure, a plurality of integrated circuits can be stacked on the circuit board 20.

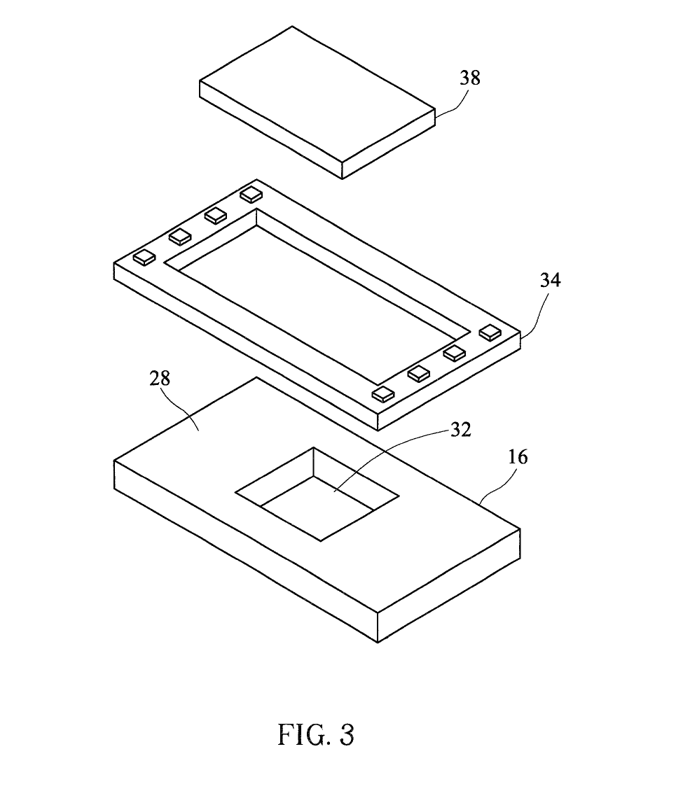

Referring to FIGS. 3 and 4, the integrated circuit body 16 includes a base layer 30, a chip 38, a plurality of first contacts 18, a projecting layer 34, and a plurality of second contacts 22. The base layer 30 has a first surface 26 and a second surface 28. A slot 32 is formed in the central portion of the base layer 30. The chip 38 is arranged on the second surface 28 of the integrated circuit body 16. The plurality of first contacts 18, arranged in the form of “Ball Grid Array (BGA)” in this embodiment, are formed on the first surface 26 of the integrated circuit body 16 so that the integrated circuit body 16 can be electrically connected to the circuit board 20. The shape of the projecting layer 34 is similar to a frame. The projecting layer 34 is adhered on the second surface 28 of the integrated circuit body 16. The plurality of second contacts 22 are formed on the projecting layer 34 so that the integrated circuit body 16 can be electrically connected to the second integrated circuit body 24, as shown in FIG. 2.

In this embodiment, the chip 38 is electrically connected to the first contacts 18 of the stackable integrated circuit via a plurality of wirings 36 penetrating through the slot 32 of the base layer 30 by wire bonding. Thus, the signals from the chip 38 can be transmitted to the circuit board 20.

It should be noted that the projecting layer 34 is provided on the second surface 28 of the integrated circuit body 16 and that the second contacts 22 are provided on the projecting layer 34. As a result, the second integrated circuit body 24 can be electrically connected to the second contacts 22 when stacking the second integrated circuit body 24 on the integrated circuit body 16, as shown in FIG. 2. Consequently, it is only necessary to use small metallic balls arranged in the form of BGA. Thus, the material for forming the small metallic balls can be saved. Furthermore, the processes for forming the small metallic balls can be made simple, the yield of the metallic balls can be improved, and the manufacturing costs can also be lowered.

By using the above-mentioned structure of the stackable integrated circuit, the following advantages can be concluded.

1. The sizes of the metallic balls can be made small, thereby saving the material for forming the metallic balls.

2. The small metallic balls can be manufactured simply, thereby improving the yield of metallic ball implantation.

3. It is possible that the size of each of the metallic balls of the integrated circuit can be made the same and that the integrated circuits can be packaged individually. Thus, the packaged integrated circuits can be stacked after packaging processes.

While the invention has been described by way of example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A stackable integrated circuit for electrically connecting to a circuit board and for a second integrated circuit body to be stacked on, the stackable integrated circuit comprising:
an integrated circuit body having a first surface and a second surface opposite to the first surface;
a plurality of first contacts formed on the first surface of the integrated circuit body for electrically connecting the integrated circuit body to the circuit board;
a projecting layer arranged on the second surface of the integrated circuit body; and
a plurality of second contacts formed on the projecting layer for electrically connecting the integrated circuit body to a second integrated circuit body.

2. The stackable integrated circuit according to claim 1, wherein the integrated circuit body comprises:
a chip;
a base layer formed with a slot penetrating through the base layer; and
a plurality of wirings penetrating through the slot for electrically connecting the chip to the base layer.

3. The stackable integrated circuit according to claim 1, wherein a plurality of metallic balls are formed on the plurality of first contacts for electrically connecting to the circuit board.

4. The stackable integrated circuit according to claim 1, wherein a plurality of metallic balls are formed on the plurality of second contacts for electrically connecting the integrated circuit body to the second integrated circuit body.

5. The stackable integrated circuit according to claim 1, wherein the second integrated circuit body comprises:
a chip;
a base layer formed with a slot penetrating through the base layer; and
a plurality of wirings penetrating through the slot for electrically connecting the chip to the base layer.
